(19) United States
(12) Patent Application Publication
(10) Pub. No.: US 2025/0208239 A1
(43) Pub. Date: Jun. 26, 2025

(54) COIL UNIT, MAGNETIC RESONANCE IMAGING APPARATUS, AND COIL UNIT COVER

(71) Applicant: FUJIFILM Corporation, Tokyo (JP)

(72) Inventors: Takeshi TANIGUCHI, Tokyo (JP); Koichi ARAI, Tokyo (JP); Yosuke OTAKE, Tokyo (JP)

(73) Assignee: FUJIFILM Corporation, Tokyo (JP)

(21) Appl. No.: 19/000,714

(22) Filed: Dec. 24, 2024

(30) Foreign Application Priority Data
Dec. 26, 2023 (JP) 2023-220061

(51) Int. Cl. G01R 33/34

(52) U.S. Cl. CPC G01R 33/34007; G01R 33/3403

(57) ABSTRACT

Provided are a coil unit, a magnetic resonance imaging apparatus, and a coil unit cover that enable dissipation of heat emitted from a subject to the outside of the coil unit. A coil unit includes one or more loop-shaped coil elements, a coil unit cover which includes a first sheet covering one surface of the coil element and a second sheet covering the other surface of the coil element and in which one or more first through-holes penetrating the first sheet and the second sheet are formed, and a first fastening member that fastens an edge of the first sheet in the first through-hole and an edge of the second sheet in the first through-hole.

### CROSS-REFERENCE TO RELATED APPLICATION

The present application claims priority under 35 U.S.C § 119 (a) to Japanese Patent Application No. 2023-220061 filed on Dec. 26, 2023, which is hereby expressly incorporated by reference, in its entirety, into the present application.

### BACKGROUND OF THE INVENTION

### 1. Field of the Invention

The present disclosure relates to a coil unit, a magnetic resonance imaging apparatus, and a coil unit cover.

### 2. Description of the Related Art

In an MRI apparatus, in a case where a tomographic image of a chest, an abdomen, or the like of a subject is obtained, a receive coil unit that is disposed on the abdomen or the like of the subject and receives a weak signal emitted from the subject is used. In addition, MRI is an abbreviation of Magnetic Resonance Imaging.

JP2010-131200A discloses an RF coil unit used in MRI imaging. The RF coil unit comprises an upper RF coil that is disposed above a subject and a lower RF coil that is disposed between the subject and a top plate.

The upper RF coil is held at a suitable position above the subject by coil support portions provided at both ends of the top plate and performs emission of an RF pulse and detection of an MR signal. The lower RF coil comprises a coil cover that has holes two-dimensionally arranged in an X-Z plane and coils that are disposed in a loop shape around the holes, and performs the emission of the RF pulse and the detection of the MR signal.

JP2012-130701A discloses an MRI receiver array used in an MRI system. The MRI receiver array disclosed in JP2012-130701A has a flexible blanket shape, is positioned to cover a patient, is fixed not to be moved or not to deviate from a proper position during an examination, and is then used.

### SUMMARY OF THE INVENTION

However, it is difficult for the receive coil unit disposed at a position covering the upper part of the subject to dissipate heat emitted from the subject. The upper RF coil disclosed in JP2010-131200A has a structure that covers the upper part of the subject in a usage state, and it is difficult for the upper RF coil to dissipate the heat emitted from the subject.

The MRI receiver array disclosed in JP2012-130701A has a structure in which a flexible cover covering an electrical component is used outside the electrical component such as a coil. This cover has a bag shape, and it is difficult for the cover to dissipate the heat emitted from the subject to the upper side of the cover.

The present disclosure has been made in view of these circumstances, and an object of the present disclosure is to provide a coil unit, a magnetic resonance imaging apparatus, and a coil unit cover that enable dissipation of heat emitted from a subject, on which the coil unit is placed, to the outside of the coil unit.

According to a first aspect of the present disclosure, there is provided a coil unit that is disposed at a measurement position of a subject. The coil unit comprises: one or more loop-shaped coil elements; a coil unit cover which includes a first sheet covering one surface of the coil element and a second sheet covering the other surface of the coil element and in which one or more first through-holes penetrating the first sheet and the second sheet are formed; and a first fastening member that fastens an edge of the first sheet in the first through-hole and an edge of the second sheet in the first through-hole.

According to the coil unit of the first aspect, the first through-hole is formed in the coil unit cover in which the coil element is accommodated, and the first fastening member that fastens the first sheet and the second sheet is provided on the edge of the first sheet in the first through-hole and the edge of the second sheet in the first through-hole. Therefore, it is possible to dissipate heat emitted from the subject, on which the coil unit is placed, to the outside of the coil unit through the first through-hole.

The coil unit may be a receive coil unit that receives a signal emitted from the subject. That is, the coil element provided in the coil unit may be a receive coil element that receives a signal emitted from the subject.

The first sheet and the second sheet may have a bag shape in which at least a portion of an outer periphery is connected.

According to a second aspect, in the coil unit according to the first aspect, the first fastening member may include a first member that is attached to the first sheet and a second member that is attached to the second sheet.

According to this aspect, it is easy to attach the first fastening member to the coil unit cover.

According to a third aspect, in the coil unit according to the second aspect, the first member and the second member may have a thickness equal to or larger than a thickness of the coil element.

According to this aspect, a force acting in a direction, in which the first fastening member is removed, is less likely to be applied between the first member and the second member, and it is possible to avoid coming-off of the first fastening member.

According to a fourth aspect, in the coil unit according to any one of the first to third aspects, the first fastening member may have an annular shape that covers an inner periphery of the first through-hole.

According to this aspect, the first fastening member can fasten the entire periphery of the edge of the first sheet in the first through-hole and the entire periphery of the edge of the second sheet in the first through-hole.

According to a fifth aspect, in the coil unit according to the fourth aspect, the first fastening member may have a structure in which a hard portion having relatively high stiffness and a soft portion having relatively low stiffness are arranged along a circumferential direction of the first through-hole, and the hard portion may have a structure for fastening the first sheet and the second sheet.

According to this aspect, flexibility of the entire coil unit can be obtained, and it is possible to fasten the edge of the first sheet in the first through-hole and the edge of the second sheet in the first through-hole.

According to a sixth aspect, in the coil unit according to any one of the first to fifth aspects, the first fastening member may have a structure in which a recessed shape and a protruding shape are fitted to each other to fasten the first sheet and the second sheet.

According to this aspect, a structure in which the efficiency of attachment and detachment can be improved can be adopted for the first fastening member.

According to a seventh aspect, in the coil unit according to any one of the first to sixth aspects, a ventilation hole that penetrates the first fastening member in a direction from an inside of the coil unit cover to the first through-hole may be formed in the first fastening member.

According to this aspect, a gas flow from the inside of the coil unit cover to the first through-hole can occur.

According to an eighth aspect, in the coil unit according to any one of the first to seventh aspects, one or more first protrusions may be formed on at least one of a surface on a side of the first sheet or a surface on a side of the second sheet in the first fastening member along a circumferential direction of the first through-hole.

In this aspect, a gas flow passing between the coil unit and the subject can occur.

According to a ninth aspect, in the coil unit according to any one of the first to eighth aspects, the first fastening member may include a second protrusion on at least one of a surface on a side of the first sheet or a surface on a side of the second sheet, and the second protrusion may be made of a material which is relatively softer than a material of the first fastening member.

According to this aspect, a gas flow passing between the coil unit and the subject occurs, and stress on the subject in a case where the second protrusion comes into contact with the subject can be alleviated.

According to a tenth aspect, in the coil unit according to any one of the first to ninth aspects, at least one of an outer surface of the first sheet or an outer surface of the second sheet may include a third protrusion that is disposed at a position where the first fastening member is disposed and that extends along a direction in which the first fastening members are arranged.

According to this aspect, a gas flow passing between the coil unit and the subject occurs, and it is possible to dissipate heat emitted from the subject to the coil unit.

According to an eleventh aspect, in the coil unit according to any one of the first to tenth aspects, the first through-hole may be formed at a position corresponding to a position of a hollow portion of the coil element.

According to this aspect, it is possible to achieve the disposition of the first through-hole in which the position of the hollow portion of the coil element.

According to a twelfth aspect, the coil unit according to any one of the first to eleventh aspects may further comprise one or more second through-holes each of which penetrates the first sheet and the second sheet and is formed at a position corresponding to a position of an overlap portion in which the coil elements adjacent to each other overlap.

According to this aspect, it is possible to improve the efficiency of dissipating the heat emitted from the subject.

According to a thirteenth aspect, the coil unit according to the twelfth aspect may further comprise a second fastening member that fastens an edge of the first sheet in the second through-hole and an edge of the second sheet in the second through-hole.

According to this aspect, the edge of the first sheet and the edge of the second sheet can be fastened in the second through-hole.

According to a fourteenth aspect, the coil unit according to any one of the first to thirteenth aspects may further comprise one or more third through-holes each of which penetrates the first sheet and the second sheet and is formed at a position corresponding to a position of a non-overlap portion in which the coil elements adjacent to each other do not overlap.

According to this aspect, it is possible to further improve the efficiency of dissipating the heat emitted from the subject.

According to a fifteenth aspect, the coil unit according to the fourteenth aspect may further comprise a third fastening member that fastens an edge of the first sheet in the third through-hole and an edge of the second sheet in the third through-hole.

According to this aspect, the edge of the first sheet and the edge of the second sheet can be fastened in the third through-hole.

According to a sixteenth aspect, in the coil unit according to any one of the first to fifteenth aspects, the first sheet and the second sheet may have a structure in which the first sheet and the second sheet are at least partially connected to each other.

According to this aspect, a bag shape can be applied as the coil unit cover.

According to a seventeenth aspect of the present disclosure, there is provided a magnetic resonance imaging apparatus comprising: a measurement device that measures a subject; and a coil unit that is disposed at a measurement position of the subject. The coil unit includes one or more loop-shaped coil elements, a coil unit cover which includes a first sheet covering one surface of the coil element and a second sheet covering the other surface of the coil element and in which one or more first through-holes penetrating the first sheet and the second sheet are formed, and a first fastening member that fastens an edge of the first sheet in the first through-hole and an edge of the second sheet in the first through-hole.

According to the magnetic resonance imaging apparatus of the seventeenth aspect of the present disclosure, it is possible to obtain the same operation and effects as those of the coil unit according to the first aspect. The configuration requirements of the coil unit according to the second to sixteenth aspects can be applied as configuration requirements of the magnetic resonance imaging apparatus according to other aspects.

According to an eighteenth aspect of the present disclosure, there is provided a coil unit cover which is used in a coil unit disposed at a measurement position of a subject and in which one or more loop-shaped coil elements are accommodated. The coil unit cover comprises: a first sheet that covers one surface of the coil element; and a second sheet that covers the other surface of the coil element, in which one or more first through-holes penetrating the first sheet and the second sheet are formed, and the coil unit cover further includes a first fastening member that fastens an edge of the first sheet in the first through-hole and an edge of the second sheet in the first through-hole.

According to the coil unit cover of the eighteenth aspect of the present disclosure, it is possible to obtain the same operation and effects as those of the coil unit cover according to the first aspect. The configuration requirements of the coil unit cover according to the second to sixteenth aspects can be applied as configuration requirements of the coil unit according to other aspects.

According to the present disclosure, the first through-hole is formed in the coil unit cover in which the coil element is accommodated, and the first fastening member for fastening the first sheet and the second sheet is provided on the edge of the first sheet in the first through-hole and the edge of the second sheet in the first through-hole. Therefore, it is possible to dissipate heat emitted from the subject, on which the coil unit is placed, to the outside of the coil unit through the first through-hole.

### BRIEF DESCRIPTION OF THE DRAWINGS

FIG. 1 is a perspective view schematically showing a configuration of an MRI apparatus.

FIG. 2 is a schematic view showing a usage state of a coil unit according to a first embodiment.

FIG. 3 is a front view showing the coil unit according to the first embodiment.

FIG. 4 is a schematic view showing a positional relationship between a coil element and a first through-hole.

FIG. 5 is a cross-sectional view showing a three-dimensional structure of the coil unit.

FIG. 6 is a front view showing a coil unit according to a second embodiment.

FIG. 7 is a front view showing a coil unit according to a third embodiment.

FIG. 8 is a schematic view showing an example of a structure of a first fastening member applied to a coil unit according to a fourth embodiment.

FIG. 9 is a schematic view showing an example of a structure of a first fastening member applied to a coil unit according to a fifth embodiment.

FIG. 10 is a schematic view showing an example of a structure of a first fastening member applied to a coil unit according to a sixth embodiment.

FIG. 11 is a schematic view showing an outer peripheral surface of the first fastening member shown in FIG. 10.

FIG. 12 is a schematic view showing an example of a structure of a first fastening member applied to a coil unit according to a seventh embodiment.

FIG. 13 is a schematic view showing an example of a structure of a coil unit according to an eighth embodiment.

FIG. 14 is a schematic view showing an example of a structure of a first fastening member applied to a coil unit according to a ninth embodiment.

FIG. 15 is a functional block diagram showing an electrical configuration of the MRI apparatus shown in FIG. 1.

FIG. 16 is a functional block diagram showing an electrical configuration of the coil unit shown in FIG. 3 and the like.

FIG. 17 is a schematic diagram showing a specific example of a decoupling circuit shown in FIG. 16.

### DESCRIPTION OF THE PREFERRED EMBODIMENTS

Hereinafter, preferred embodiments of the present invention will be described in detail with reference to the accompanying drawings. In addition, in the following description and the accompanying drawings, the same components are denoted by the same reference numerals, and a duplicated description thereof will be omitted. Further, in the following embodiments, in a case where a plurality of components are described and listed, it can be interpreted that at least one of the plurality of components is included.

### Example of Configuration of MRI Apparatus

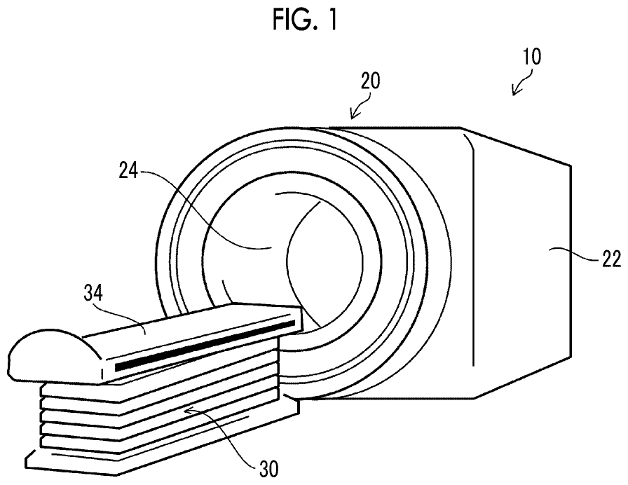

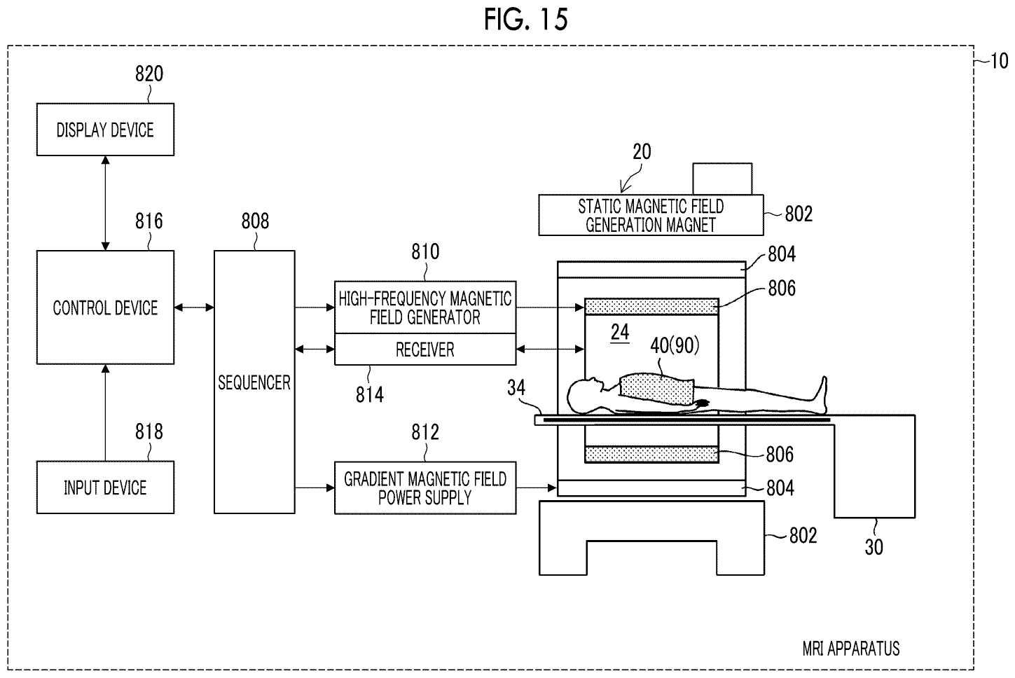

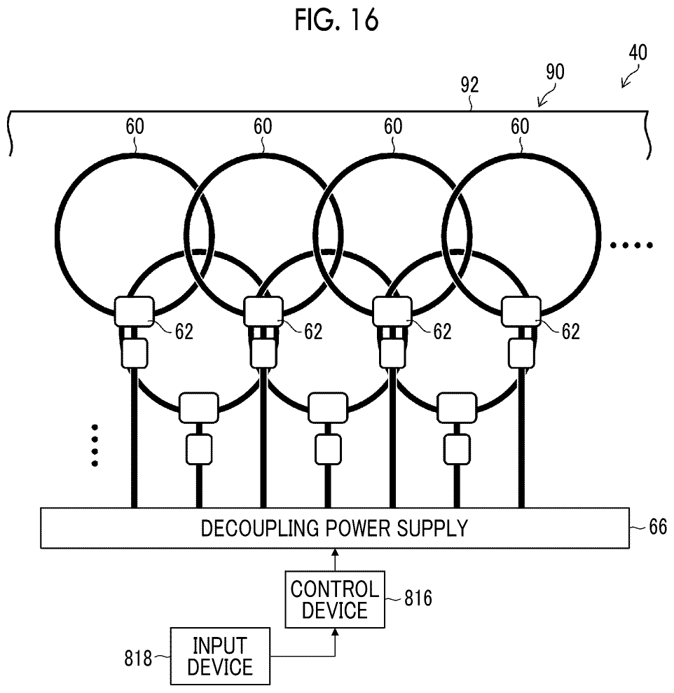

FIG. 1 is a perspective view schematically showing a configuration of an MRI apparatus. An MRI apparatus 10, which is a magnetic resonance imaging apparatus, comprises a measurement device 20 including a gantry 22, a bed 30, and a control device. The measurement device 20 and the bed 30 are disposed in an imaging room, and the control device is disposed in an operation room. FIG. 1 shows a state in which the bed 30 is set at a position where a medical image of a subject is captured. The bed 30 is configured to be movable manually or automatically on an installation surface of the MRI apparatus 10. In addition, the control device, the imaging room, and the operation room are not shown. The control device is denoted by reference numeral 816 and is shown in FIG. 15.

The bed 30 comprises a top plate 34 on which the subject undergoing an image diagnostic examination is placed. The top plate 34 is movable by a bed driving device in each of an up-down direction, a forward direction in which the top plate 34 enters an imaging space 24 of the gantry 22, a backward direction in which the top plate 34 exits the imaging space 24, and a lateral direction which is orthogonal to the forward direction and is orthogonal to the up-down direction.

The control device functions as a control device that controls a control unit of a machine room to control each device, such as the measurement device and the bed 30, and executes MRI imaging for acquiring an NMR signal. In addition, the control device functions as a device that performs processing of various types of data including a process of reconstructing the image on the basis of the NMR signal acquired from the measurement device 20, a communication process via a network, display of processing results, storage of data, and the like.

The NMR signal obtained from the measurement device 20 is subjected to signal processing and then subjected to digital image processing. The reconstructed image is displayed on a display device of the control device. In addition, NMR is an English abbreviation of Nuclear Magnetic Resonance.

### Outline of Coil Unit

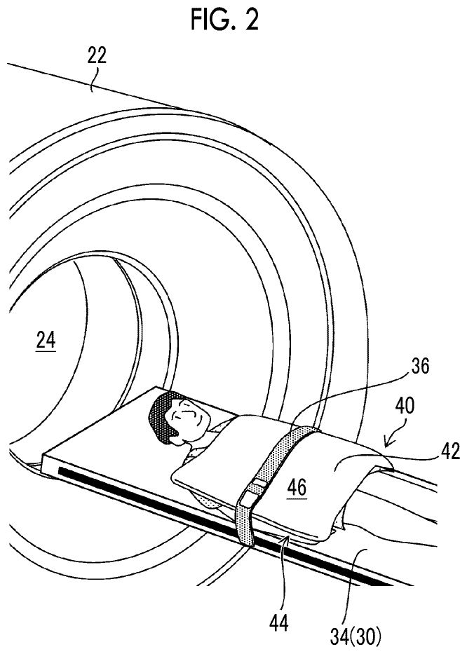

FIG. 2 is a schematic view showing a usage state of a coil unit according to a first embodiment. Further, in FIG. 2, the top plate 34 is shown as the bed 30, and a main body and the like of the bed 30 are not shown.

FIG. 2 shows a state in which a coil unit 40 is hung at a measurement position from a chest to an abdomen of the subject. The coil unit 40 is fixed to the chest and abdomen of the subject using a belt 36 provided in the bed 30.

A structure that has a blanket shape and is lighter and more flexible than an integrally molded type is applied to the coil unit 40. That is, the coil unit 40 has a structure in which the outside of a component, such as a coil element, is covered by a bag-shaped coil unit cover 42. A material forming the coil unit cover 42 may be a urethane-based resin, such as polyurethane, a polyamide synthetic resin, such as nylon, or the like.

Here, the bag shape may be a state in which a first sheet in contact with the subject and a second sheet opposite to the subject are joined to each other at least on one side. For example, in a case where the planar shape of each of the first sheet and the second sheet is a quadrangle, at least one side of the quadrangle may be joined. In a non-bag-shaped coil unit 40, the first sheet and the second sheet may be separated from each other.

A first through-hole penetrating the coil unit cover 42 is formed in the coil unit 40. The first through-hole penetrates a first sheet 44 that comes into contact with the subject and a second sheet 46 that is opposite to the first sheet 44 with electrical components interposed therebetween.

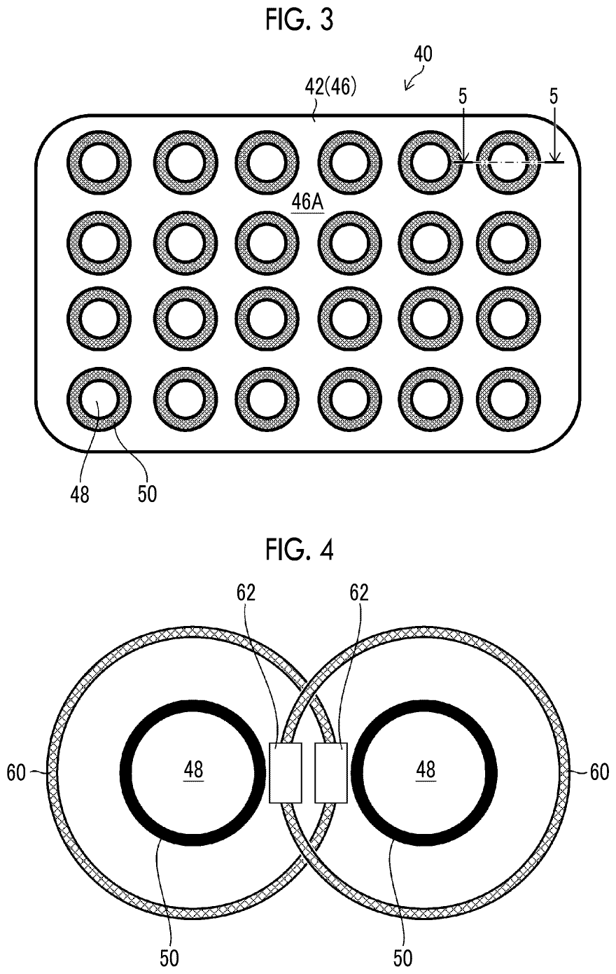

In a coil unit to which a coil unit cover in which the first through-hole is not formed is applied, it is difficult to dissipate heat emitted from a human body to the outside of the coil unit. The first through-hole is formed in the coil unit cover 42 of the coil unit 40 according to the embodiment. Therefore, it is possible to dissipate the heat emitted from the subject to the outside of the coil unit 40 through the first through-hole. Further, in FIG. 2, the first through-hole is not shown. The first through-hole is denoted by reference numeral 48 and is shown in FIG. 3.

### Specific Example of Coil Unit According to First Embodiment

FIG. 3 is a front view showing the coil unit according to the first embodiment. FIG. 3 shows a second surface 46A of the second sheet 46 of the coil unit 40. The coil unit 40 shown in FIG. 3 is a receive coil unit having a blanket shape, and a plurality of first through-holes 48 are formed in the coil unit cover 42.

A ring-shaped first fastening member 50 is attached to an edge of the coil unit cover 42 in each of the plurality of first through-holes 48. An example of the material forming the first fastening member 50 is a synthetic resin having a predetermined stiffness. In addition, the ring-shaped first fastening member 50 described in the embodiment is an example of a fastening member having an annular shape that covers the inner periphery of the first through-hole.

FIG. 3 shows an aspect in which the same number of through-holes as the coil elements provided in the coil unit 40 are formed in the coil unit cover 42. That is, FIG. 3 shows a 24-channel coil unit 40 that includes coil elements functioning as 24 receive coils.

The diameter of the first through-hole 48 is less than the diameter of the coil element and may be defined, for example, in a range of 10% to 80% of the diameter of the coil element in which a single wire is used. The diameter of the first through-hole 48 may be an inner diameter of the first fastening member 50. For example, in a case where the diameter of the coil element is 100 millimeters, the inner diameter of the first fastening member 50 defined as the diameter of the first through-hole 48 is less than 100 millimeters and may be, for example, any value from 10 millimeters to 80 millimeters.

The diameter of the coil element is defined according to electrical specifications, structural conditions, and the like of the coil unit 40. The diameter of the coil element may be equal to or greater than 1.0 millimeter and equal to or less than 10.0 millimeters.

FIG. 4 is a schematic view showing a positional relationship between the coil element and the first through-hole. The first through-hole 48 is formed in a hollow portion that is a space present in a central portion of the loop-shaped coil element 60 accommodated in the coil unit cover 42. That is, the first fastening member 50 attached to the first through-hole 48 is disposed in a loop of the coil element 60. In addition, the first through-hole 48 may be formed to avoid the position of a decoupling circuit 62 that is electrically connected to the coil element 60.

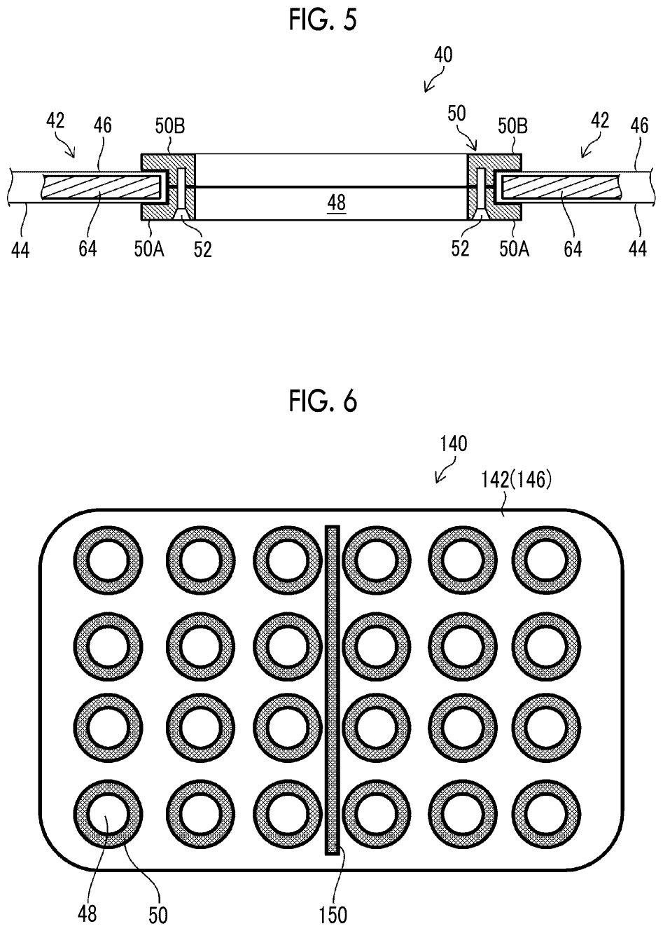

FIG. 5 is a cross-sectional view showing a three-dimensional structure of the coil unit. FIG. 5 shows a cross section of the coil unit 40 taken along a cross-sectional line 5-5 shown in FIG. 3. The first fastening member 50 comprises a first member 50A that is attached to the first sheet 44 and a second member 50B that is attached to the second sheet 46. Adhesion may be applied to the attachment of the first member 50A to the first sheet 44. The same applies to the attachment of the second member 50B to the second sheet 46.

The first fastening member 50 has a structure in which the first member 50A and the second member 50B are fixed by a screw 52. Therefore, the first member 50A and the second member 50B are prevented from easily coming apart from each other. FIG. 5 shows an aspect in which the first member 50A and the second member 50B are fastened at two positions. However, the number of screwing positions may be two or more.

The first fastening member 50 has a thickness that is about 1 mm to 5 mm larger than the thickness of the coil unit cover 42 on each of the side of the first sheet 44 and the side of the second sheet 46. The thickness of the coil unit cover 42 may be the thickness of a content 64, such as the coil element 60, the thickness of the first sheet 44, and the thickness of the second sheet 46. However, the thickness of the content 64 does not include the thickness of the decoupling circuit 62 shown in FIG. 4.

### Operation and Effects of Coil Unit According to First Embodiment

The coil unit 40 according to the first embodiment can obtain the following operation and effects.
[1]

The first through-hole 48 penetrating the bag-shaped coil unit cover 42 is formed in the coil unit 40. The ring-shaped first fastening member 50 is attached to the first through-hole 48. Therefore, the coil unit 40 can dissipate the heat emitted from the subject to the outside of the coil unit 40 through the first through-hole 48, and the retention of the heat between the coil unit and the subject is suppressed.
[2]

The first fastening member 50 comprises the first member 50A that is attached to the first sheet 44 and the second member 50B that is attached to the second sheet 46. The first member 50A and the second member 50B are fastened by the screw 52. Therefore, the first member 50A and the second member 50B are prevented from easily coming apart from each other.
[3]

The first fastening member 50 has a thickness that is about 1 mm to 5 mm larger than the thickness of the coil unit cover 42 on each of the side of the first sheet 44 and the side of the second sheet 46. This makes it possible to fasten the first member 50A and the second member 50B in a state in which the content 64 is accommodated in the coil unit 40.

The ring-shaped resin member attached to the first through-hole 48 is given as an example of the first fastening member 50 provided in the coil unit 40 according to the first embodiment. However, the first fastening member 50 may be a fastener, a snap button, or the like that fastens the edge of the first sheet 44 in the first through-hole 48 and the edge of the second sheet 46 in the first through-hole 48.

The planar shape of the first through-hole 48 is not limited to a circle. Any shape, such as a polygon including a quadrangle or an ellipse, may be applied as the planar shape of the first through-hole 48. The planar shape of the first fastening member 50 may be determined according to the planar shape of the first through-hole 48.

### Specific Example of Coil Unit According to Second Embodiment

FIG. 6 is a front view showing a coil unit according to a second embodiment. Hereinafter, the difference between a coil unit 140 according to the second embodiment and the coil unit 40 according to the first embodiment will be mainly described.

The coil unit 140 shown in FIG. 6 is provided with a fastener 150 on a second sheet 146. The fastener 150 is disposed at a position of a central portion of a long side of the second sheet 146 whose planar shape is a rectangular shape and extends in a direction parallel to a short side of the second sheet 146.

In the coil unit 140, the fastener 150 is opened, and it is easy to accommodate the content 64 and the like in the coil unit cover 142 and to take out the content 64 and the like from the coil unit cover 142. This makes it easy to replace the coil unit cover 142 in the coil unit 140.

The total length of the fastener 150 can be defined from the viewpoint of taking out the content 64 and the like from the coil unit cover 142. For example, the total length of the fastener 150 may be equal to or greater than 50% of the length of the short side of the second sheet 46 and less than 100% of the length.

FIG. 6 shows an aspect in which the second sheet 146 is provided with the fastener 150. However, the fastener 150 may be provided in the first sheet that is not shown in FIG. 6. In addition, the fastener 150 may be provided in each of the first sheet that is not shown in FIG. 6 and the second sheet 146.

One or more snap buttons may be provided instead of the fastener 150. In addition, the fastener 150 and the snap button may be used in combination. For example, the first sheet may be provided with the fastener 150, and the second sheet 146 may be provided with one or more snap buttons.

### Operation and Effects of Coil Unit According to Second Embodiment

In the coil unit 140 according to the second embodiment, at least one of the first sheet or the second sheet 146 is provided with the fastener 150. This makes it easy to replace the coil unit cover 142.

### Specific Example of Coil Unit according to Third Embodiment

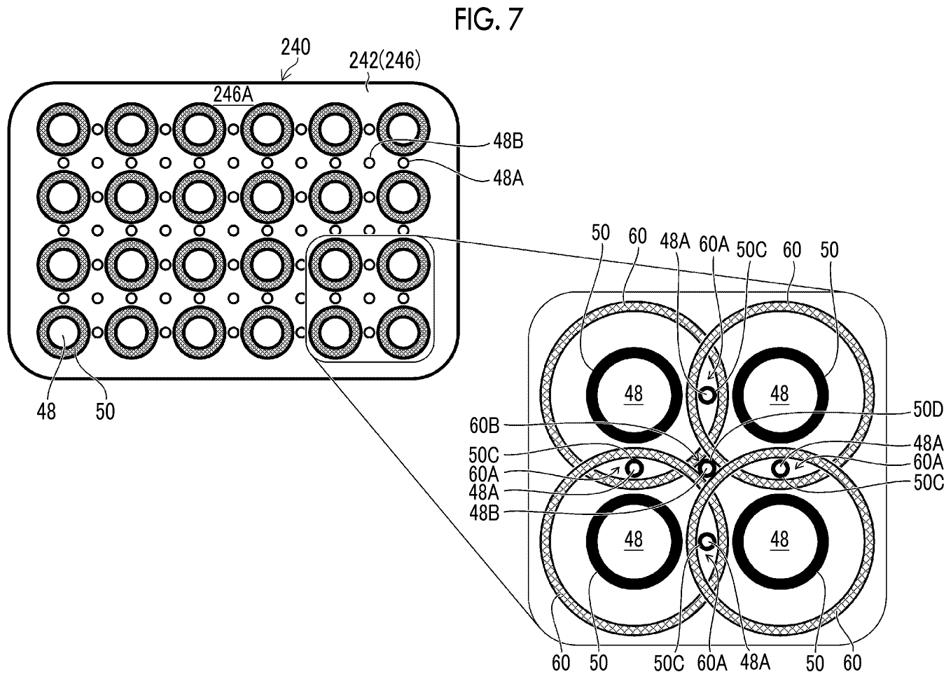

FIG. 7 is a front view showing a coil unit according to a third embodiment. FIG. 7 shows a second surface 246A of a second sheet 246 of a coil unit cover 242. FIG. 7 includes an enlarged view of a portion of the coil unit 240. For convenience of description, the coil element 60 accommodated in the coil unit cover 242 is shown in the enlarged view of the coil unit 240.

In the coil unit 240 shown in FIG. 7, a second through-hole 48A is formed at a position of an overlap region 60A that is an overlap portion in which a plurality of coil elements 60 adjacent to each other overlap. In addition, in the coil unit 240, a third through-hole 48B is formed at a position of a non-overlap region 60B that is a non-overlap portion in which the plurality of coil elements 60 adjacent to each other do not overlap.

The second through-hole 48A has a size corresponding to the area of the overlap region 60A.

A second fastening member 50C is attached to the second through-hole 48A. The second fastening member 50C has a size corresponding to the second through-hole 48A. A third fastening member 50D is attached to the third through-hole 48B. The third fastening member 50D has a size corresponding to the third through-hole 48B. The second and third fastening members 50C and 50D are made of the same material as the first fastening member 50 and have the same structure as the first fastening member 50.

### Operation and Effects of Coil Unit According to Third Embodiment

In the coil unit 240 according to the third embodiment, the second through-hole 48A is formed at the position of the overlap region 60A in which the plurality of coil elements 60 adjacent to each other overlap. In addition, in the coil unit 240, the third through-hole 48B is formed at the position of a non-overlap region 60B in which the plurality of coil elements 60 adjacent to each other do not overlap. This makes it possible to efficiently dissipate the heat emitted from the subject from a space between the coil unit 240 and the subject to the outside of the coil unit 240.

### Specific Example of Coil Unit According to Fourth Embodiment

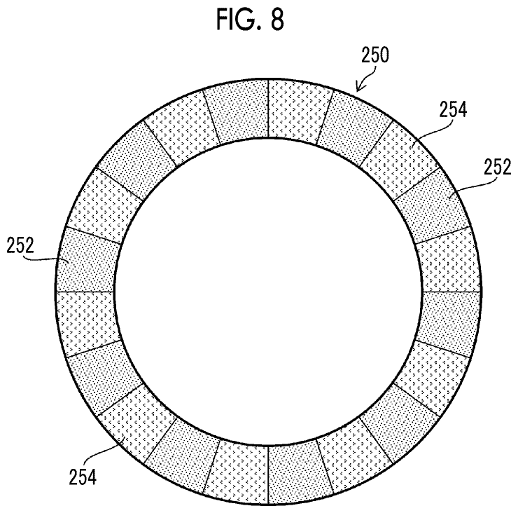

FIG. 8 is a schematic view showing an example of a structure of a first fastening member that is applied to a coil unit according to a fourth embodiment. FIG. 8 shows one of a plurality of first fastening members 250 attached to an edge of a coil unit cover in each of a plurality of first through-holes 48 provided in the coil unit.

The first fastening member 250 shown in FIG. 8 comprises a hard portion 252 having stiffness required to fasten the first member and the second member and a soft portion 254 having flexibility. A hole into which the screw 52 is inserted and which is used for the screwing shown in FIG. 5 is formed in the hard portion 252.

In the first fastening member 250, the hard portions 252 and the soft portions 254 are alternately disposed along a circumferential direction of the first through-hole 48. In addition, in the first fastening member 250, the hard portion 252 and the soft portion 254 have the same length in the circumferential direction of the first through-hole 48.

An example of a material forming the hard portion 252 is a synthetic resin having predetermined stiffness. An example of a material forming the soft portion 254 is a foamed resin having lower stiffness than the hard portion 252. The ratio of the hard portion 252 to the soft portion 254 in the first fastening member 250 is appropriately determined within a range in which the first fastening member 250 has predetermined stiffness as a whole.

The first fastening member 250 may have a structure in which the hard portion 252 and the soft portion 254 are provided in one of the first member and the second member and a plurality of hard portions 252 are dispersedly disposed in the other of the first member and the second member.

### Operation and Effects of Coil Unit According to Fourth Embodiment

The first fastening member 250 provided in the coil unit according to the fourth embodiment comprises the hard portion 252 having relatively high stiffness and the soft portion 254 having lower stiffness than the hard portion 252. As a result, the function of fastening the first sheet and the second sheet is maintained as a whole in the coil unit, and predetermined flexibility conforming to the body shape of the subject in a usage state is achieved.

### Specific Example of Coil Unit According to Fifth Embodiment

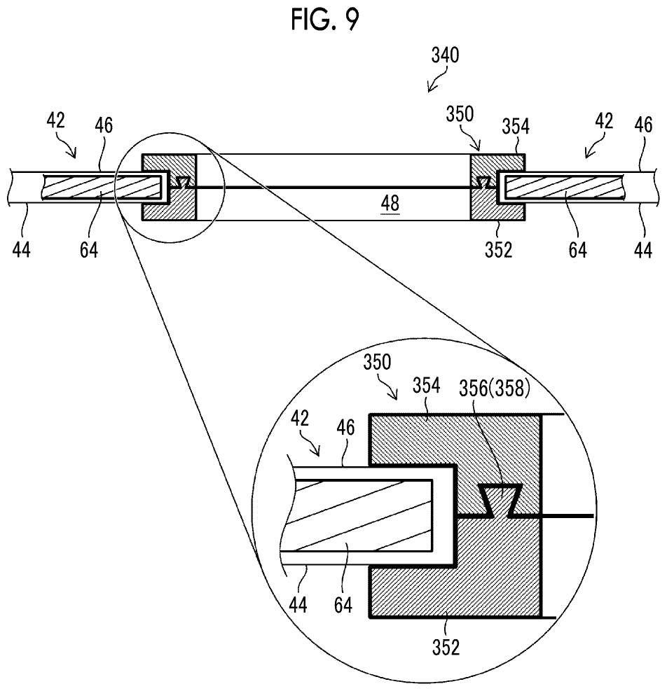

FIG. 9 is a schematic view showing an example of a structure of a first fastening member applied to a coil unit according to a fifth embodiment. FIG. 9 shows a cross-sectional view of a coil unit 340 along the same cross-sectional line as the cross-sectional line 5-5 shown in FIG. 3 and an enlarged view of a first fastening member 350.

A first member 352 comprises a protruding portion 356, and a second member 354 comprises a recessed portion 358 having a shape that is freely fitted to the protruding portion 356. The protruding portion 356 and the recessed portion 358 are disposed at positions where the protruding portion 356 and the recessed portion 358 are freely fitted to each other. Two sets of the protruding portions 356 and the recessed portions 358 are shown in FIG. 9. However, the number of sets of the protruding portions 356 and the recessed portions 358 may be two or more.

A truncated cone in which the diameter increases from a base end to a tip may be applied as the shape of the protruding portion 356. A shape in which the diameter decreases from the base end to the tip may be applied to the recessed portion 358 fitted to the protruding portion 356 to which the truncated cone shape in which the diameter increases from the base end to the tip is applied.

In addition, the protruding portion 356 described in the embodiment is an example of a protruding shape, and the recessed portion 358 is an example of a recessed shape.

### Operation and Effects of Coil Unit According to Fifth Embodiment

In the coil unit 340 according to the fifth embodiment, the first member 352 constituting the first fastening member 350 comprises the protruding portion 356, and the second member 354 comprises the recessed portion 358 having a shape that is freely fitted to the protruding portion 356. This makes it easy to attach and detach the first member 352 and the second member 354 and makes it possible to improve work efficiency in a case where the first member 352 and the second member 354 are fastened.

### Specific Example of Coil Unit According to Sixth Embodiment

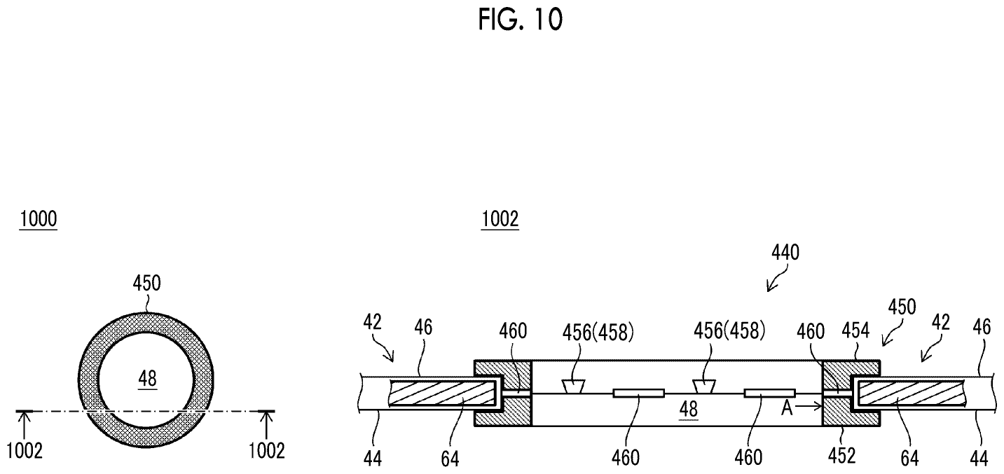

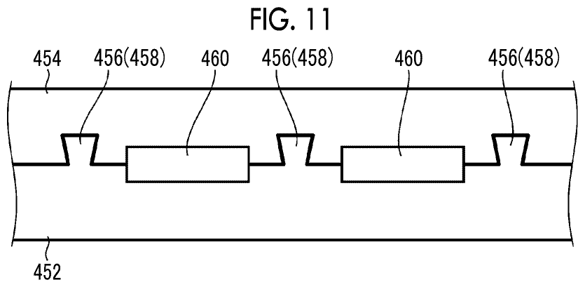

FIG. 10 is a schematic view showing an example of a structure of a first fastening member that is applied to a coil unit according to a sixth embodiment. FIG. 10 includes a front view 1000 of a first fastening member 450 provided in a coil unit 440 and a cross-sectional view 1002 taken along a cross-section line 1002-1002 shown in the front view 1000. FIG. 11 is a schematic view showing an inner peripheral surface of the fastening member shown in FIG. 10. FIG. 11 shows an arrow view as seen from an arrow A shown in the cross-sectional view 1002 of FIG. 10.

In the first fastening member 450 provided in the coil unit 440, a ventilation hole 460 that penetrates a surface on the side of the first through-hole 48 and a surface on the inside of the coil unit cover 42 is formed. The ventilation hole 460 is disposed to avoid the positions of a protruding portion 456 and a recessed portion 458 for fastening a first member 452 and a second member 454. FIGS. 10 and 11 show an aspect in which a plurality of ventilation holes 460 are formed. However, the number of ventilation holes 460 may be one or more.

A rectangle is given as an example of the planar shape of the ventilation hole 460 in FIGS. 10 and 11. However, any shape, such as a circle or a polygon, is applied as the planar shape of the ventilation hole 460. The planar shape of the ventilation hole 460 may be the shape of the ventilation hole 460 in a case where the ventilation hole 460 is viewed from the first through-hole 48.

FIGS. 10 and 11 show an aspect in which the ventilation hole 460 is formed at the position across the first member 452 and the second member 454. However, the ventilation hole 460 may be formed in any of the first member 452 or the second member 454.

### Operation and Effects of Coil Unit According to Sixth Embodiment

In the coil unit 440 according to the sixth embodiment, the ventilation hole 460 is formed in the first fastening member 450. The surface on the side of the first through-hole 48 communicates with the surface on the inner side of the coil unit cover 42 through the ventilation hole 460. This makes it possible to dissipate the heat emitted from the content 64 to the outside of the coil unit 440 through the ventilation hole 460 and the first through-hole 48.

### Specific Example of Coil Unit According to Seventh Embodiment

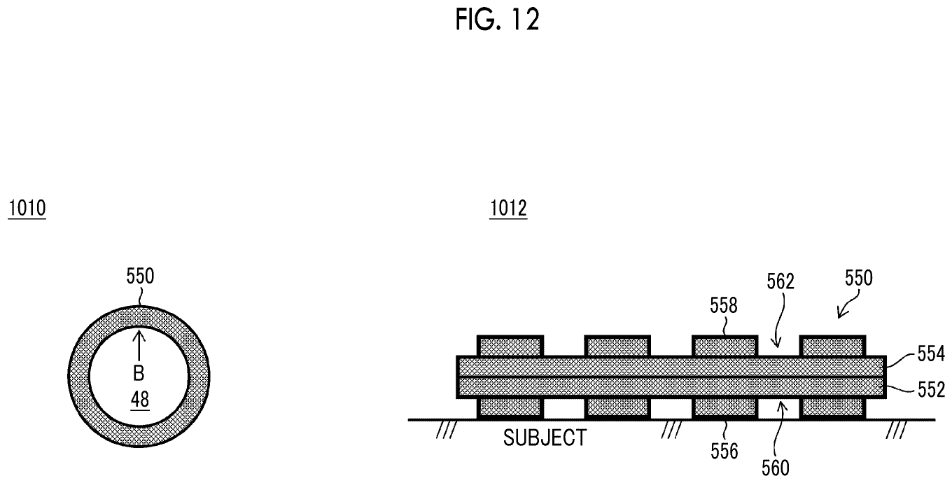

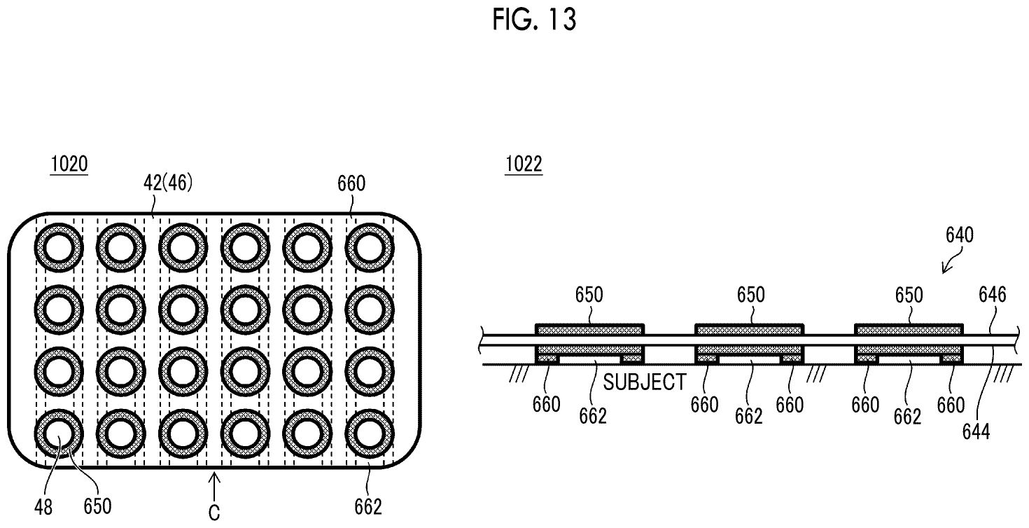

FIG. 12 is a schematic view showing an example of a structure of a first fastening member applied to a coil unit according to a seventh embodiment. FIG. 12 includes a front view 1010 of a first fastening member 550 and an arrow view 1012 as seen from an arrow B in the front view 1010.

A plurality of first protrusions 556 are formed on a first member 552 of the first fastening member 550. The height of the first protrusion 556 may be approximately 5 millimeters. The height of the first protrusion 556 is the shortest length from a base end to a tip of the first protrusion 556.

A space 560 between the first protrusions 556 adjacent to each other functions as an air flow passage between the first fastening member 550 and the subject in a case where the first member 552 comes into contact with the subject. The width of the space 560 and the number of spaces 560 in a direction in which the plurality of first protrusions 556 are disposed can be defined from the viewpoint of air circulation. The widths of the plurality of spaces 560 may be the same or may be different from each other.

The width of the first protrusion 556 may be the same as or different from the width of the space 560. For example, the width of the first protrusion 556 may be defined in a range of 0.1 times to 10 times the width of the space 560.

A quadrangular prism, a cylinder, a truncated cone, or the like may be applied as the three-dimensional shape of the first protrusion 556. The same three-dimensional shape or different three-dimensional shapes may be applied to the plurality of first protrusions 556.

A material forming the first protrusion 556 may be the same as or different from a material forming the first member 552. A material that does not cause stress to the subject may be applied to the tip of the first protrusion 556.

In the first fastening member 550 shown in FIG. 12, a second protrusion 558 is formed on a second member 554. The height, width, number, three-dimensional shape, and material of the second protrusion 558 can be defined to be the same as the first protrusion 556.

FIG. 12 shows an aspect in which the first protrusion 556 is formed on the first member 552 and the second protrusion 558 is formed on the second member 554 of the first fastening member 550. However, in the coil unit according to the seventh embodiment, at least one of the first protrusion 556 or the second protrusion 558 may be formed.

### Operation and Effects of Coil Unit According to Seventh Embodiment

The coil unit according to the seventh embodiment can obtain the following effects.
[1]

A plurality of first protrusions 556 are formed on the first member 552 of the first fastening member 550. Therefore, in a case where the first sheet to which the first member 552 is joined is brought into contact with the subject and the coil unit is used, the space 560 formed between the first protrusions 556 adjacent to each other functions as the air flow passage between the subject and the coil unit, and it is possible to dissipate the heat emitted from the subject from the end of the coil unit to the outside of the coil unit.
[2]

A plurality of second protrusions 558 are formed on the second member 554 of the first fastening member 550. Therefore, even in a case where the second sheet is brought into contact with the subject and the coil unit is used, the space 562 formed between the second protrusions 558 adjacent to each other functions as the air flow passage between the subject and the coil unit, and it is possible to dissipate the heat emitted from the subject from the end of the coil unit to the outside of the coil unit.

### Specific Example of Coil Unit According to Eighth Embodiment

FIG. 13 is a schematic view showing an example of a structure of a coil unit according to an eighth embodiment. FIG. 13 includes a front view 1020 of a coil unit 640 and an arrow view 1022 as seen from an arrow C shown in the front view 1020.

The coil unit 640 includes a plurality of third protrusions 660 each of which has a length corresponding to a length from one end to the other end of a first sheet 644 and extends in a direction in which first fastening members 650 are arranged. The third protrusion 660 is disposed at a position where the third protrusion 660 overlaps the first fastening member 650 and does not overlap the first through-hole 48.

A space 662 that extends from one end to the other end of the coil unit 640 is formed between the third protrusions 660 adjacent to each other. The space 662 functions as an air flow passage in a space between the coil unit 640 and the subject.

FIG. 13 shows the third protrusion 660 that extends in a direction along a short side of the coil unit 640 having a rectangular planar shape. The coil unit 640 may be provided with the third protrusion 660 that extends in a direction along a long side of the rectangular planar shape.

FIG. 13 shows an aspect in which the third protrusions 660 are provided on both sides of the first through-hole 48 in the first fastening member 650. However, the third protrusion 660 may be provided on at least one of one side or the other side of the first through-hole 48 in the first fastening member 650. In the coil unit 640, the third protrusions 660 may be provided on a second sheet 646.

The height of the third protrusion 660 is defined from the viewpoint of air circulation in the space between the coil unit 640 and the subject. For example, the height of the third protrusion 660 may be the same as the height of the first fastening member 650. The height of the third protrusion 660 can be defined as a distance from a base end to a tip of the third protrusion 660.

The same material as that forming the first fastening member 650 may be applied to the third protrusion 660. A material that does not cause stress to the subject may be applied to the tip of the third protrusion 660.

### Operation and Effects of Coil Unit According to Eighth Embodiment

The coil unit 640 according to the eighth embodiment is provided with the plurality of third protrusions 660 on the surface in contact with the subject. The third protrusion 660 extends in a direction along one side of the coil unit 640 and has a length corresponding to the length of the one side. This makes it possible to dissipate the heat emitted from the subject to the outside of the coil unit 640 through the space between the third protrusions 660 adjacent to each other.

### Specific Example of Coil Unit According to Ninth Embodiment

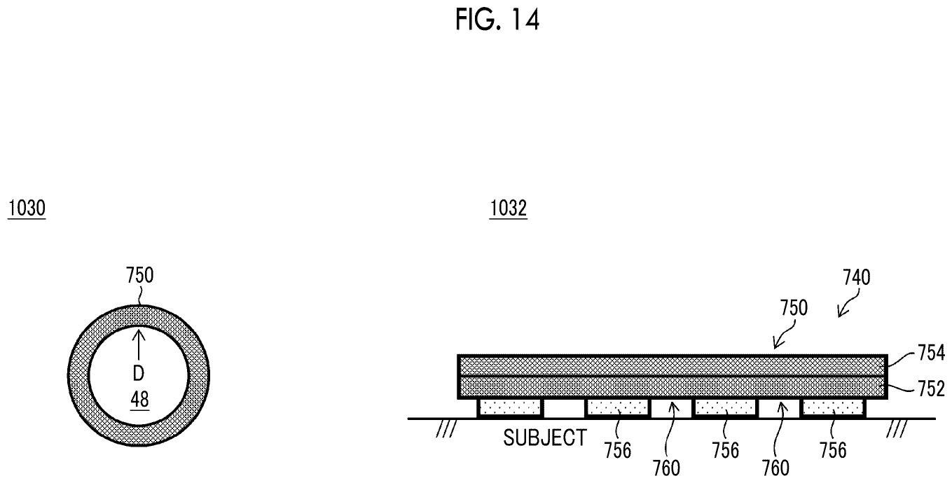

FIG. 14 is a schematic view showing an example of a structure of a first fastening member applied to a coil unit according to a ninth embodiment. FIG. 14 includes a front view 1030 of a first fastening member 750 and an arrow view 1032 as seen from an arrow D shown in the front view 1030.

A first member 752 of the first fastening member 750 is provided with a plurality of buffer materials 756 on a surface that comes into contact with the subject in a case where a coil unit 740 is used. The plurality of buffer materials 756 are disposed around the first through-hole 48 along the circumference of the first through-hole 48. An interval at which the plurality of buffer materials 756 are disposed is defined from the viewpoint of air circulation in a space 760 between the buffer materials 756 adjacent to each other.

A cylinder, a quadrangular prism, a truncated cone, or the like may be applied as a three-dimensional shape of the buffer material 756. The planar shape of the buffer material 756 as viewed in the direction in which the first through-hole 48 extends may be, for example, a shape in which a portion of an arc and a circle is missing.

The height of the buffer material 756 may be the same as the height of a portion of the first member 752 that protrudes from the first sheet. For the height of the buffer material 756, a portion that is crushed due to the self-weight of the coil unit 740 in the usage state of the coil unit 740 may be considered. For example, the height of the buffer material 756 in the usage state of the coil unit 740 may be about 5 millimeters.

A material, such as a foamed resin or a porous material, that is relatively soft and causes less stress to the subject is applied as the buffer material 756. The buffer material 756 may be provided at the tip of a second member 754. In this aspect, the coil unit 740 is used while the second sheet is in contact with the subject.

### Operation and Effects of Coil Unit According to Ninth Embodiment

In the coil unit 740 according to the ninth embodiment, in the first fastening member 750, a plurality of buffer materials 756 are provided at the tip of at least one of the first member 752 or the second member 754. The surface of the coil unit 740 on which the buffer materials 756 are provided is brought into contact with the subject. This makes it possible to dissipate the heat emitted from the subject to the outside of the coil unit 740 through the space between the buffer materials 756 adjacent to each other.

In addition, a material, such as a foamed resin or a porous material, that is relatively soft and causes less stress to the subject is applied as the buffer material 756. This makes it possible to relieve the stress on the subject in a case where the coil unit 740 is used.

### Electrical Configuration of MRI Apparatus

FIG. 15 is a functional block diagram showing an electrical configuration of the MRI apparatus shown in FIG. 1. The measurement device 20 comprises a static magnetic field generation magnet 802, a gradient magnetic field coil 804, a transmission coil 806, and a receive coil 90. The transmission coil can be referred to as an RF coil using an abbreviation of Radio Frequency. FIG. 15 shows the receive coil 90 configured as the coil unit 40.

The static magnetic field generation magnet 802 generates a uniform static magnetic field in the imaging space 24 in which the subject is accommodated. The gradient magnetic field coil 804 generates a gradient magnetic field in the imaging space 24. In addition, the imaging space can be referred to as a bore.

The transmission coil 806 generates a high-frequency magnetic field that causes a nucleus of an atom constituting a tissue of the subject to produce an NMR signal. The receive coil 90 detects the NMR signal emitted from the subject.

The top plate 34 on which the subject is placed is moved to the imaging space 24, an examination part of the subject is positioned at the center of the static magnetic field of the imaging space 24, and the position of the top plate 34 is fixed.

A sequencer 808 transmits a command to a high-frequency magnetic field generator 810 according to an imaging sequence. The high-frequency magnetic field generator 810 that has received the command generates a high-frequency magnetic field in the imaging space 24. In addition, the sequencer 808 transmits a command to a gradient magnetic field power supply 812 according to the imaging sequence. The gradient magnetic field power supply 812 that has received the command generates the gradient magnetic field in the imaging space 24.

The high-frequency magnetic field generated in the imaging space 24 is applied as an RF pulse, which is a pulsed high-frequency magnetic field, to the subject through the transmission coil 806. The NMR signal emitted from the subject is received by the receive coil 90. The NMR signal received by the receive coil 90 is detected by a receiver 814.

In addition, the gradient magnetic field coil 804 is configured to include gradient magnetic field coils in each of the X direction, the Y direction, and the Z direction. The gradient magnetic field coil 804 is supplied with an excitation current from the gradient magnetic field power supply 812 and generates the gradient magnetic field in each of the X direction, the Y direction, and the Z direction.

The sequencer 808 sets a nuclear magnetic resonance frequency that is a reference for detection in the receiver 814. The sequencer 808 applies a predetermined timing and applies a magnetic field with predetermined intensity to control the operation of each unit. As the imaging sequence, a pulse sequence in which an RF pulse, a gradient magnetic field, and a timing, and signal reception intensity are described is applied to the sequencer 808. In addition, various types of pulse sequences are known depending on the purpose. However, a detailed description thereof will be omitted here.

The control device 816 controls the operation of the MRI apparatus 10 through the sequencer 808. The control device 816 receives the NMR signal detected by the receiver 814 and performs various types of signal processing such as image reconstruction.

The receiver 814 performs quadrature phase detection on the NMR signal of the analog wave using the set detection reference frequency, converts the NMR signal into raw data, and transmits the raw data to the control device 816. The raw data transmitted to the control device 816 can be referred to as an echo signal or measurement data.

The control device 816 receives various instruction input signals input by the operator operating an input device 818. The control device 816 controls the overall operation of each unit of the MRI apparatus 10 on the basis of the instruction input signal. In addition, the control device 816 performs, for example, a process of converting the echo signal in the spatial frequency domain received through the sequencer 808 into an image in a real space using inverse Fourier transform to generate an MRI image.

A computer, such as a personal computer, a workstation, or a server computer, is applied to the control device 816. The computer applied to the control device 816 comprises a processor, a memory which is a main storage device, a storage which is an auxiliary storage device, an input/output interface, a bus, and the like. The processor, the memory, the storage, and the input/output interface are electrically connected to each other via a bus.

The processor may include one or more CPUs. The processor may include a GPU. The control device 816 may be configured to include processors such as a DSP, an ASIC, a PLD, and an FPGA.

In addition, CPU is an abbreviation of Central Processing Unit, and GPU is an abbreviation of Graphics Processing Unit. DSP is an abbreviation of Digital Signal Processor, and ASIC is an abbreviation of Application Specific Integrated Circuit. PLD is an abbreviation of Programmable Logic Device, and FPGA is an abbreviation of Field Programmable Gate Array.

The memory includes a RAM. The memory may include a ROM. The storage may include a hard disk. The storage may include a solid state drive. The storage may be a combination of a hard disk and a solid state drive. The storage may include an external storage device such as a removable disk.

Further, RAM is an abbreviation of Random Access Memory, and ROM is an abbreviation of Read Only Memory. The hard disk drive can be referred to as an HDD by using an abbreviation of Hard Disk Drive. The solid state drive can be referred to as an SSD by using an abbreviation of Solid State Drive.

In the control device 816, various programs including a control program stored in the ROM are deployed in the RAM. The processor is configured to execute one or more commands included in the program deployed in the RAM. Therefore, the functions of each unit of the MRI apparatus 10 are implemented, and the reception and transmission of various types of information are implemented using the input/output interface.

The control device 816 may receive a captured image of the subject transmitted from a camera that images the subject, analyze the captured image to detect the physique, posture, and the like of the subject, and control the operation of the bed 30 on the basis of the detection results.

The input device 818 includes a mouse, a keyboard, and the like. The input device 818 functions as a GUI that receives an input from the operator. In addition, GUI is an abbreviation of Graphical User Interface. A touch panel display may be applied to the input device 818. The touch panel display may be a tablet device.

That is, the input device 818 functions as a GUI for the operator to input, for example, commands to start, stop, and pause the MRI apparatus 10. The input device 818 functions as a GUI for selecting a pulse sequence and for inputting imaging conditions, processing conditions, and the like.

The display device 820 displays the examination image of the subject acquired by the MRI apparatus 10. The display device 820 displays various types of information related to the operation of the MRI apparatus 10. The MRI apparatus 10 may adopt a multi-display form comprising a plurality of display devices 820.

### Electrical Configuration of Coil Unit

FIG. 16 is a functional block diagram showing an electrical configuration of the coil unit shown in FIG. 3 and the like. The coil unit 40 comprises a receive coil 90 and a receive coil sheet 92. The receive coil 90 comprises a plurality of coil elements 60, a plurality of decoupling circuits 62, and a decoupling power supply 66. The receive coil 90 is accommodated in the coil unit cover 42 shown in FIG. 3.

Each of the plurality of coil elements 60 comprises one decoupling circuit 62. Each of the plurality of decoupling circuits 62 is electrically connected to the decoupling power supply 66 and is supplied with power from the decoupling power supply 66.

The receive coil sheet 92 has a size that covers a measurement range of the subject, and the plurality of coil elements 60, the plurality of decoupling circuits 62, and the decoupling power supply 66 are disposed on the receive coil sheet 92. In the receive coil sheet 92 on which the plurality of coil elements 60 and the like are disposed, a through-hole corresponding to the first through-hole 48 shown in FIG. 3 and the like is formed.

The coil unit 40 is configured to have flexibility as a whole and to be thin and lightweight. The measurement of various examination parts is achieved by the coil unit 40 regardless of the physique, posture, and the like of the subject.

Each of the plurality of coil elements 60 provided in the receive coil 90 functions as one channel of a multi-channel antenna that receives the NMR signal emitted from a biological tissue of the subject. The coil element 60 is adjusted to resonate at a predetermined frequency. The predetermined frequency is determined on the basis of the atomic nucleus of the object to be observed in the biological tissue and the magnetic field intensity.

The transmission coil 806 applies an RF pulse to the subject. The application of the RF pulse to the subject causes the atomic nuclei of the atoms constituting the biological tissue of the subject to generate the NMR signals. In a case where the coil element 60 is changed to a resonant state due to the supply of power from the decoupling power supply 66 to the coil element 60 during a period for which the RF pulse is applied to the subject, the coil element 60 receives an excessive RF magnetic field. As a result, there is a concern that a peripheral circuit related to the coil element 60 will be damaged.

For this reason, during the period for which the RF pulse is transmitted from the transmission coil 806 to the subject, the decoupling power supply 66 supplies power to the coil element 60 to switch the coil element 60 to a detuned state in which the coil element 60 does not resonate. In a case where the transmission of the RF pulse from the transmission coil 806 is stopped, the decoupling power supply 66 stops the supply of power to the coil element 60 to switch the coil element 60 to the resonant state.

That is, on the basis of a command signal for designating the coil element 60 transmitted from the control device 816, the decoupling power supply 66 supplies power to the designated coil element 60 to switch the designated coil element 60 to the resonant state. On the other hand, the decoupling power supply 66 does not supply power to a non-designated coil element 60 to switch the non-designated coil element 60 to the detuned state.

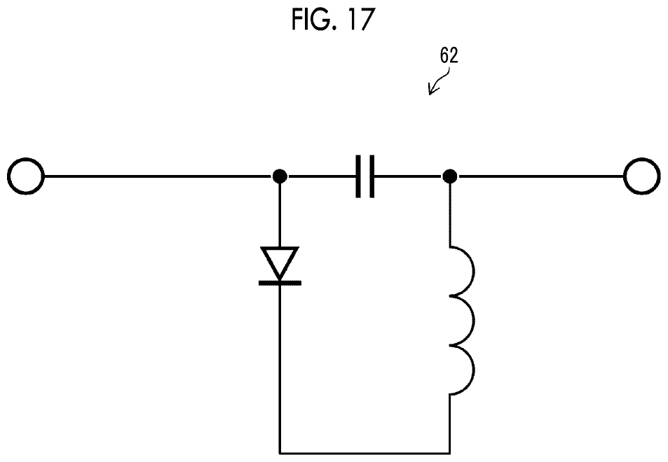

FIG. 17 is a schematic diagram showing a specific example of the decoupling circuit shown in FIG. 16. FIG. 17 shows an example of a circuit that is extremely simplified for convenience of description. The decoupling circuit 62 is a resonance circuit that removes the magnetic coupling between the receive coil including the plurality of coil elements 60 and the transmission coil 806. The decoupling circuit 62 comprises a diode, an inductor, and a capacitor. Each of the inductor and the capacitor is a heat generating element that is irradiated with high-frequency magnetic field energy and generates heat.

### For Hardware Configuration of Each Processing Unit

A hardware structure of a processing unit that executes various processes of the control device 816 shown in FIG. 15 is, for example, the following various processors.

The various processors include a CPU which is a general-purpose processor executing a program to function as various processing units, a GPU, a programmable logic device, such as an FPGA, which is a processor whose circuit configuration can be changed after manufacture, and a dedicated electric circuit, such as an ASIC, which is a processor having a dedicated circuit configuration designed to perform a specific process.

One processing unit may be configured by one of the various processors or by two or more processors of the same type or different types. For example, one processing unit may be configured by a plurality of FPGAs, a combination of a CPU and an FPGA, or a combination of a CPU and a GPU. Further, a plurality of processing units may be configured by one processor. A first example of the configuration in which a plurality of processing units are configured by one processor is a form in which one processor is configured by a combination of one or more CPUs and software and this processor functions as a plurality of processing units, as represented by a computer such as a client or a server. A second example of the configuration is a form in which a processor that implements the functions of the entire system including a plurality of processing units using one integrated circuit (IC) chip is used, as represented by a system-on-chip (SoC). As described above, various processing units are configured using one or more of the various processors as a hardware structure.

In addition, specifically, the hardware structure of the various processors is an electric circuit (circuitry) obtained by combining circuit elements such as semiconductor elements.

### Example of Application to Medical Image Diagnostic Examination System

The measurement device 20 shown in FIG. 1 and the control device 816 shown in FIG. 15 may be electrically connected to each other via any network such that data communication can be performed therebetween, thereby configuring a medical image diagnostic examination system. The data communication between the measurement device 20 and the control device 816 may be wired communication or wireless communication.

The present disclosure is not limited to the above-described embodiments, and various modifications can be made without departing from the gist of the technical idea of the present disclosure.

### EXPLANATION OF REFERENCES

10: MRI apparatus
40: coil unit
42: coil unit cover
44: first sheet
46: second sheet
48: first through-hole
50: first fastening member
60: coil element

What is claimed is:

1. A coil unit that is disposed at a measurement position of a subject, the coil unit comprising:
one or more loop-shaped coil elements;
a coil unit cover which includes a first sheet covering one surface of the coil element and a second sheet covering the other surface of the coil element and in which one or more first through-holes penetrating the first sheet and the second sheet are formed; and
a first fastening member that fastens an edge of the first sheet in the first through-hole and an edge of the second sheet in the first through-hole.

2. The coil unit according to claim 1,
wherein the first fastening member includes
a first member that is attached to the first sheet, and
a second member that is attached to the second sheet.

3. The coil unit according to claim 2,
wherein the first member and the second member have a thickness equal to or larger than a thickness of the coil element.

4. The coil unit according to claim 1,
wherein the first fastening member has an annular shape that covers an inner periphery of the first through-hole.

5. The coil unit according to claim 4,
wherein the first fastening member has a structure in which a hard portion having relatively high stiffness and a soft portion having relatively low stiffness are arranged along a circumferential direction of the first through-hole, and
the hard portion has a structure for fastening the first sheet and the second sheet.

6. The coil unit according to claim 1,
wherein the first fastening member has a structure in which a recessed shape and a protruding shape are fitted to each other to fasten the first sheet and the second sheet.

7. The coil unit according to claim 1,
wherein a ventilation hole that penetrates the first fastening member in a direction from an inside of the coil unit cover to the first through-hole is formed in the first fastening member.

8. The coil unit according to claim 1,
wherein one or more first protrusions are formed on at least one of a surface on a side of the first sheet or a surface on a side of the second sheet in the first fastening member along a circumferential direction of the first through-hole.

9. The coil unit according to claim 1,
wherein the first fastening member includes a second protrusion on at least one of a surface on a side of the first sheet or a surface on a side of the second sheet, and the second protrusion is made of a material which is relatively softer than a material of the first fastening member.

10. The coil unit according to claim 1,
wherein at least one of an outer surface of the first sheet or an outer surface of the second sheet includes a third protrusion that is disposed at a position where the first fastening member is disposed and that extends along a direction in which the first fastening members are arranged.

11. The coil unit according to claim 1,
wherein the first through-hole is formed at a position corresponding to a position of a hollow portion of the coil element.

12. The coil unit according to claim 1, further comprising:
one or more second through-holes each of which penetrates the first sheet and the second sheet and is formed at a position corresponding to a position of an overlap portion in which the coil elements adjacent to each other overlap.

13. The coil unit according to claim 12, further comprising:
a second fastening member that fastens an edge of the first sheet in the second through-hole and an edge of the second sheet in the second through-hole.

14. The coil unit according to claim 1, further comprising:
one or more third through-holes each of which penetrates the first sheet and the second sheet and is formed at a position corresponding to a position of a non-overlap portion in which the coil elements adjacent to each other do not overlap.

15. The coil unit according to claim 14, further comprising:
a third fastening member that fastens an edge of the first sheet in the third through-hole and an edge of the second sheet in the third through-hole.

16. The coil unit according to claim 1,
wherein the first sheet and the second sheet have a structure in which the first sheet and the second sheet are at least partially connected to each other.

17. A magnetic resonance imaging apparatus comprising:
a measurement device that measures a subject; and
a coil unit that is disposed at a measurement position of the subject,
wherein the coil unit includes
one or more loop-shaped coil elements,
a coil unit cover which includes a first sheet covering one surface of the coil element and a second sheet covering the other surface of the coil element and in which one or more first through-holes penetrating the first sheet and the second sheet are formed, and
a first fastening member that fastens an edge of the first sheet in the first through-hole and an edge of the second sheet in the first through-hole.

18. A coil unit cover which is used in a coil unit disposed at a measurement position of a subject and in which one or more loop-shaped coil elements are accommodated, the coil unit cover comprising:
a first sheet that covers one surface of the coil element; and
a second sheet that covers the other surface of the coil element,
wherein one or more first through-holes penetrating the first sheet and the second sheet are formed, and
the coil unit cover further includes a first fastening member that fastens an edge of the first sheet in the first through-hole and an edge of the second sheet in the first through-hole.
